(19) United States
(12) Patent Application Publication
(10) Pub. No.: US 2015/0187574 A1
(43) Pub. Date: Jul. 2, 2015

(54) IGZO with Intra-Layer Variations and Methods for Forming the Same

(71) Applicants: LG Display Co. Ltd.; Intermolecular Inc., San Jose, CA (US)

(72) Inventors: Minh Huu Le, San Jose, CA (US); Yoon-Kyung Chang, Gyeonggi-do (KR); Seon-Mee Cho, Santa Clara, CA (US); Min-Cheol Kim, Gyeonggi-do (KR); Sang Lee, San Jose, CA (US); Kwon-Sik Park, Gangnamu-gu (KR); Woosup Shin, Gyeonggi-do (KR)

(73) Assignees: LG Display Co. Ltd.; Intermolecular Inc., San Jose, CA (US)

(21) Appl. No.: 14/140,797

(22) Filed: Dec. 26, 2013

(51) Int. Cl. H01L 21/02; H01L 29/66

(52) U.S. Cl. CPC H01L 21/02631; H01L 29/66969; H01L 21/02554; H01L 21/02422; H01L 21/02472

(57) ABSTRACT

Embodiments described herein provide method for forming crystalline indium-gallium-zinc oxide (IGZO) with intra-layer variations and methods for forming such IGZO. At least a portion of a substrate is positioned in a processing chamber. A first sub-layer of an IGZO layer is formed above the at least a portion of the substrate while the at least a portion of the substrate is in the processing chamber. The first sub-layer of the IGZO layer is formed using a first set of processing conditions. A second sub-layer of the IGZO layer is formed above the first sub-layer of the IGZO layer while the at least a portion of the substrate is in the processing chamber. The second sub-layer of the IGZO layer is formed using a second set of processing conditions. The second set of processing conditions is different than the first set of processing conditions.

### TECHNICAL FIELD

The present invention relates to indium-gallium-zinc oxide (IGZO). More particularly, this invention relates to methods for forming IGZO with intra-layer variations, as well as methods for forming IGZO devices, such as IGZO thin film transistors (TFTs), incorporating such IGZO.

### BACKGROUND OF THE INVENTION

Indium-gallium-zinc oxide (IGZO) devices, such as IGZO thin-film transistors (TFTs) have attracted a considerable amount of attention due to the associated low cost, room temperature manufacturing processes with good uniformity control, high mobility for high speed operation, and the compatibility with transparent, flexible, and light, and large size display applications, especially in the next generation of displays. Due to these attributes, IGZO TFTs may even be favored over low cost amorphous silicon TFTs and relatively high mobility polycrystalline silicon TFT for advanced display device applications. IGZO devices typically utilize amorphous IGZO (a-IGZO).

Recent developments in the display industry suggest that the use of crystalline IGZO may provide improved electrical and chemical stability. However, little work has been done to determine how to form crystalline IGZO, or convert a-IGZO to crystalline IGZO, using already-existing manufacturing and processing equipment (e.g., physical vapor deposition (PVD) processing, furnace annealing, etc.).

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 is a cross-sectional view of a substrate with gate electrode formed above.

FIG. 2 is a cross-sectional view of the substrate of FIG. 1 with a gate dielectric layer formed above the gate electrode and the substrate.

FIG. 3 is a cross-sectional view of the substrate of FIG. 2 with a first portion of an indium-gallium-zinc oxide (IGZO) layer formed above the gate dielectric layer.

FIG. 4 is a cross-sectional view of the substrate of FIG. 3 with a second portion of an IGZO layer formed above the first portion of the IGZO layer.

FIG. 5 is a cross-sectional view of the substrate of FIG. 4 with an IGZO channel layer formed above the gate dielectric layer.

FIG. 6 is a cross-sectional view of the substrate of FIG. 5 with source and drain electrodes formed above the IGZO channel layer.

FIG. 7 is a cross-sectional view of the substrate of FIG. 6 with a passivation layer formed above the source and drain electrodes.

FIG. 8 is a simplified cross-sectional diagram illustrating a physical vapor deposition (PVD) tool according to some embodiments.

FIG. 9 is a simplified cross-sectional diagram illustrating an in-line PVD tool according to some embodiments.

FIG. 10 is a flow chart illustrating a method for forming IGZO according to some embodiments.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed.

Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

The term “horizontal” as used herein will be understood to be defined as a plane parallel to the plane or surface of the substrate, regardless of the orientation of the substrate. The term “vertical” will refer to a direction perpendicular to the horizontal as previously defined. Terms such as “above”, “below”, “bottom”, “top”, “side” (e.g. sidewall), “higher”, “lower”, “upper”, “over”, and “under”, are defined with respect to the horizontal plane. The term “on” means there is direct contact between the elements. The term “above” will allow for intervening elements.

Embodiments described herein provide methods for forming indium-gallium-zinc oxide (IGZO) (e.g., amorphous and/or crystalline IGZO) in such a way as to create intra-layer variations in the IGZO. These variations may be used to, for example, improve the electrical and chemical stability IGZO, or the device in which the IGZO is used.

In some embodiments, this is accomplished by changing the processing conditions during the IGZO deposition process. That is, in some embodiments, a first sub-layer (or portion) of an IGZO layer is formed/deposited using a first set of processing conditions, and then a second sub-layer of the IGZO layer is formed (above the first sub-layer) in the same processing chamber using a second set of processing conditions. In some embodiments, the first set of processing conditions may cause the first sub-layer of the IGZO layer to serve as a nucleation layer and thus influence the characteristics of the remainder (e.g., the second sub-layer) of the IGZO layer, such as the crystallinity (e.g., a crystalline phase and/or a crystalline phase combined/mixed with an amorphous phase and/or microcrystalline structure).

In some embodiments, the chemical composition of the gaseous environment to which the substrate is exposed during the deposition process is changed (i.e., between the forming of the first sub-layer of the IGZO layer and the second sub-layer of the IGZO layer). However, in some embodiments, other processing conditions are changed, such as gaseous pressure, processing temperature, target power, duty cycle, the distance between the substrate and the target(s), etc.

In some embodiments, the first and second sub-layers of the IGZO layer are formed using physical vapor deposition (PVD). In some embodiments, the PVD tool is an “in-line” PVD tool in which the substrate is moved through the processing chamber during the IGZO deposition process.

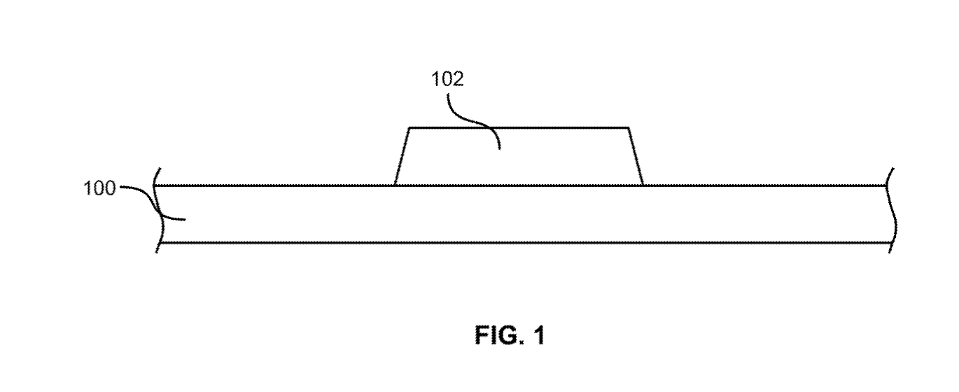

FIGS. 1-7 illustrate a method for forming an IGZO thin-film transistor (or more generically, an IGZO device), according to some embodiments. Referring now to FIG. 1, a substrate 100 is shown. In some embodiments, the substrate 100 is transparent and is made of, for example, glass. The substrate 100 may have a thickness of, for example, between about 0.01 centimeters (cm) and about 0.5 cm. Although only a portion of the substrate 100 is shown, it should be understood that the substrate 100 may have a width of, for example, between about 5.0 cm and about 4.0 meters (m). Although not shown, in some embodiments, the substrate 102 may have a dielectric layer (e.g., silicon oxide) formed above an upper surface thereof. In such embodiments, the components described below are formed above the dielectric layer. Also, in some embodiments, the substrate 100 is at least partially made of a of a semiconductor material (e.g., silicon, germanium, gallium arsenide, etc.). For example, in some embodiments, the substrate includes glass with a layer of semiconductor material formed thereon. Additionally, in some embodiments, the substrate 100 may include (or be made of) a polymer or a flexible material (e.g., a flexible polymer).

Still referring to FIG. 1, a gate electrode 102 is formed above the transparent substrate 100. In some embodiments, the gate electrode 102 is made of a conductive material, such as copper, silver, aluminum, manganese, molybdenum, tantalum, chrome, titanium, or a combination thereof. The gate electrode may have a thickness of, for example, between about 20 nanometers (nm) and about 500 nm. Although not shown, it should be understood that in some embodiments, a seed layer (e.g., copper or a copper alloy) is formed between the substrate 100 and the gate electrode 102.

It should be understood that the various components on the substrate, such as the gate electrode 102 and those described below, are formed using processing techniques suitable for the particular materials being deposited, such as PVD (e.g., single target or multiple target sputtering in some embodiments), chemical vapor deposition (CVD), electroplating, etc. Furthermore, although not specifically shown in the figures, it should be understood that the various components on the substrate 100, such as the gate electrode 102, may be sized and shaped using a photolithography process and an etching process, as is commonly understood, such that the components are formed above selected regions of the substrate 100.

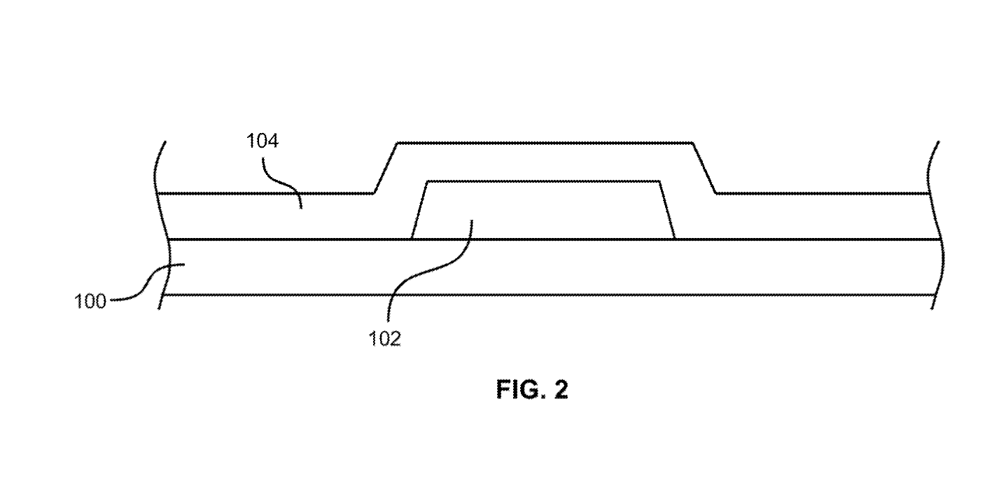

Referring to FIG. 2, a gate dielectric layer 104 is then formed above the gate electrode 102 and the exposed portions of the substrate 100. The gate dielectric layer 104 may be made of, for example, silicon oxide, silicon nitride, or a high-k dielectric (e.g., having a dielectric constant greater than 3.9), such as zirconium oxide, hafnium oxide, or aluminum oxide, or a combination thereof (e.g., a bi- or tri-layer dielectric layer). In some embodiments, the gate dielectric layer 104 has a thickness of, for example, between about 10 nm and about 500 nm.

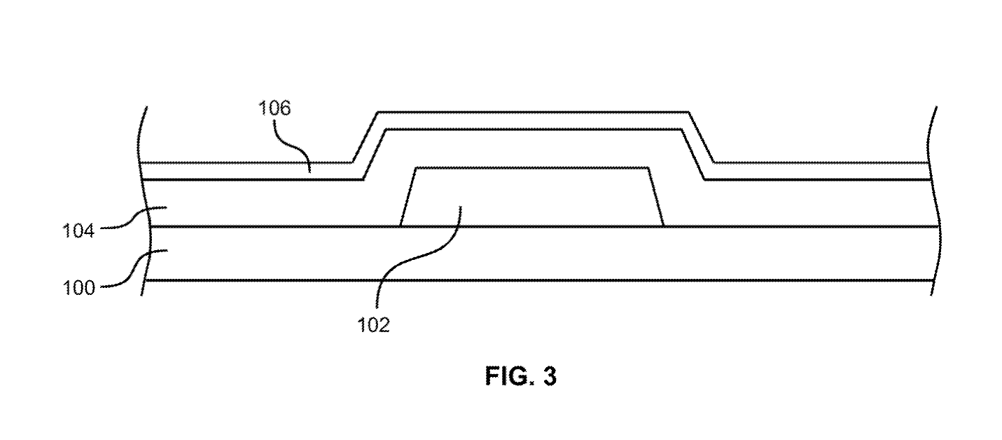

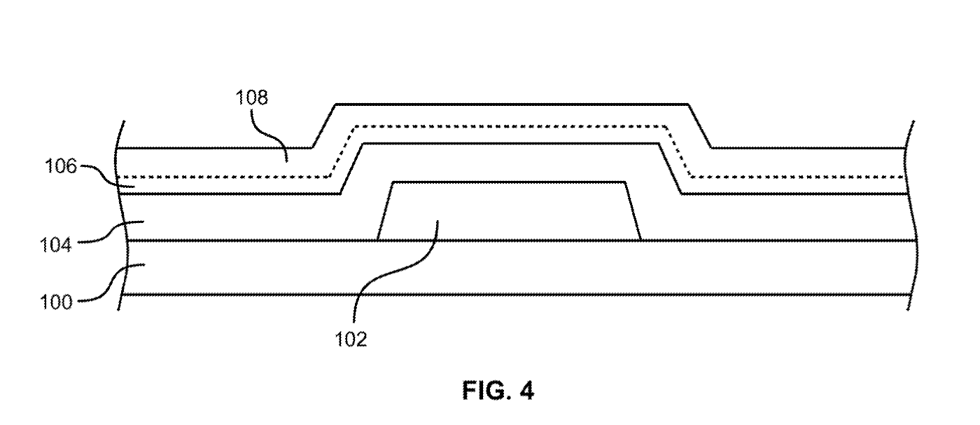

As shown in FIGS. 3 and 4, an IGZO layer is then formed above the gate dielectric layer 104. As described in greater detail below, the IGZO layer may be considered to be formed in two (or more) sub-layers (or portions). However, it should be understood that in some embodiments a single processing step is used to form/deposit the IGZO (and/or the sub-layers thereof).

Referring specifically to FIG. 3, a first sub-layer (or portion) 106 of an IGZO layer is formed above the gate dielectric 104. The first sub-layer 106 may be made of IGZO in which a ratio of the respective elements is, for example, 1:1:1:1-4. In some embodiments, the IGZO layer 108 is formed using PVD. The first sub-layer 106 may be deposited from a single target that includes indium, gallium, and zinc, perhaps in combination with oxygen and/or a nitride (e.g., an indium-gallium-zinc alloy target or an IGZO target), but two or more targets may also used (e.g., co-sputtering with an indium-zinc target and a gallium target). The first sub-layer 106 may have a thickness of, for example, between about 1 nm and about 100 nm, such as about 20 nm. In some embodiments, the IGZO within the first sub-layer 106 is deposited as amorphous IGZO (a-IGZO). However, in some embodiments, the IGZO is formed or deposited using processing conditions to enhance the crystalline structure thereof.

In some embodiments, the first sub-layer 106 is formed/deposited using a first set of processing conditions. The processing conditions may include (or be related to or associated with) the chemical composition, pressure, and/or flow of the gaseous environment (e.g., within a processing chamber) in which the IGZO is formed, the processing temperature, target power, a distance between the substrate and the target(s), or a combination thereof. In some embodiments, the processing condition may (also) include the “duty cycle” at which the particular processing tool (e.g., a PVD tool) is operated, an amount of power provided to the target(s) (e.g., PVD targets), or a combination thereof.

As will be appreciated by one skilled in the art, the duty cycle of a PVD process may refer to the portion of the time of the deposition process during which a negative charge is applied to the target(s) (i.e., during alternating current (AC) sputtering). That is, in some embodiments, during the deposition process, the charge on the target(s) is alternated between a negative charge (e.g., about −300 V) and a non-negative charge (e.g., a positive charge, such as about +20 V). If the PVD tool is operated at a duty cycle of, for example, 70%, during the deposition process, the charge applied to the target(s) is negative, in total, for 70% of the time. One skilled in the art will appreciate that in such an embodiment, the charge may be switched at a frequency of, for example, between about 50 hertz (Hz) and about 13.56 megahertz (MHz). If the PVD tool is operated at a duty cycle of 100%, the charge on the target(s) is negative throughout the deposition process. Such a manner of operation may be considered to be direct current (DC) sputtering.

Referring now to FIG. 4, a second sub-layer 108 of the IGZO layer is then formed above the first sub-layer 106. As with the first sub-layer 106, the second sub-layer 108 may be made of IGZO in which a ratio of the respective elements is 1:1:1:1-4. The second sub-layer 108 may have a thickness of, for example, between about 25 nm and about 100 nm, such as about 80 nm. Thus, in some embodiments, the first sub-layer 106 and the second sub-layer 108 may have a combined thickness of between about 26 nm and about 200 nm.

As discussed above, the second sub-layer 108 may be formed using the same processing step (e.g., PVD) as the first sub-layer 106. In some embodiments, the substrate 100 (or at least the portion of the substrate 100 above which the IGZO is deposited) remains in the processing chamber (e.g., of a stationary PVD tool or an in-line PVD tool) used to deposit the IGZO between the initiation of the formation of the first sub-layer 106 of the IGZO layer and the cessation of the formation of the second sub-layer 108 of the IGZO layer.

In some embodiments, the second sub-layer 108 is formed/deposited using a second set of processing conditions. That is, the processing conditions used to form/deposit the IGZO may be changed (i.e., from the first set of processing conditions to the second set of processing conditions) during the formation/deposition of the IGZO layer such that the first sub-layer 106 of the IGZO layer is the portion of the IGZO layer that is formed using the first set of processing conditions, and the second sub-layer 108 of the IGZO layer is the portion of the IGZO layer that is formed using the second set of processing conditions.

For example, in some embodiments, the processing conditions are changed such that the first sub-layer 106 is formed in a gaseous environment having a first flow rate of gas (e.g., argon) and the second sub-layer is formed in a gaseous environment having a second flow rate of gas. As another example, the chemical composition of the gaseous environment may be changed during the deposition process (e.g., the first sub-layer 106 is deposited in a mixture of argon, oxygen, nitrogen, and/or nitrous oxide, while the second sub-layer 108 is deposited in pure argon). As a further example, the duty cycle is changed during the deposition process. It should be understood that more than one of the processing conditions may be changed during the deposition process (e.g., the chemical composition of the gaseous environment and the processing temperature). It should also be understood that in some embodiments the processing conditions are changed more than once (e.g., with a “gradient” such that more than two sub-layers/portions of the IGZO layer are formed).

In some embodiments, the first set of processing conditions and/or the second set of processing conditions are selected such that the IGZO is formed/deposited with particular properties or characteristics. For example, the first sub-layer 106 of the IGZO layer may be formed in such a way to enhance the crystalline structure thereof (e.g., primarily along the c-axis), which may then in turn promote a similar crystalline structure in the second sub-layer 108 of the IGZO layer (i.e., the first sub-layer 106 may serve as a nucleation layer).

Although not specifically shown, in some embodiments, the IGZO layer (i.e., the first and second sub-layers 106 and 108), along with the other components shown in FIG. 4, may then undergo an annealing process. In some embodiments, the annealing process includes a relatively low temperature (e.g., less than about 530° C., preferably less than about 450° C.) heating process in, for example, a gaseous environment (e.g., nitrogen, oxygen, ambient/air, argon, nitrous oxide, or a combination thereof) to (further) enhance the crystalline structure of the IGZO. The heating process may occur for between about 1 minute and about 200 minutes. After the annealing (or heating) process, the IGZO layer may (substantially) include crystalline IGZO (c-IGZO). As used herein a “crystalline” material (e.g., c-IGZO) may be considered to be one that is more than 30% crystalline by volume, as determined by a technique such as X-ray Diffraction (XRD) (e.g., 2θ=30.9 degrees). In some embodiments, the c-IGZO is c-axis aligned crystal (CAAC) IGZO, as is commonly understood.

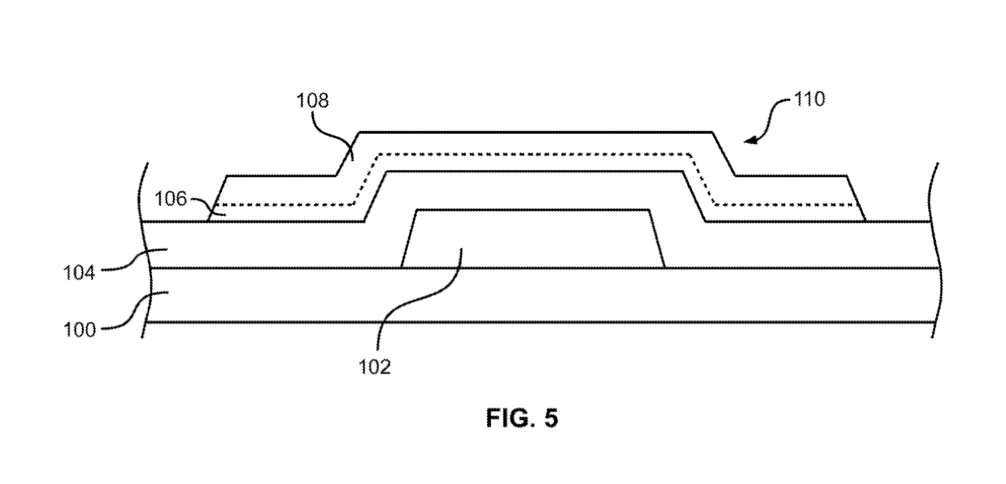

Referring to FIG. 5, after the annealing process, the IGZO layer (i.e., the first and second sub-layers 106 and 108) is patterned (e.g., etched) to form an IGZO channel (or channel layer) 110 above the gate dielectric layer 104, over the gate electrode 102. As shown, the IGZO channel layer 110 is made of both the first and second sub-layers 106 and 108 of the previously formed IGZO layer.

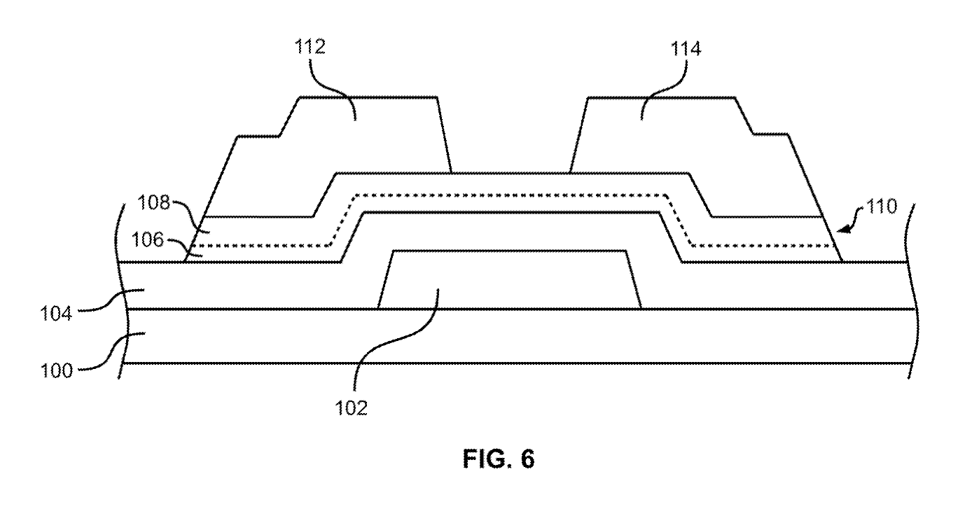

Referring now to FIG. 6, a source electrode (or region) 112 and a drain electrode (or region) 114 are then formed above the IGZO channel layer 110. As shown, the source electrode 112 and the drain electrode 114 lie on ends of the IGZO channel layer 110. As will be appreciated by one skilled in the art, the source electrode 112 and the drain electrode 114 may be defined as shown in FIG. 6 using a “back-channel etch” (BCE) process to, for example, form the gap between the source electrode 112 and the drain electrode 114, which is vertically aligned with the gate electrode 102.

However, in some embodiments, an etch-stop layer, as is commonly understood, may be formed above the IGZO channel layer 110 to facilitate the defining of the source electrode 112 and the drain electrode 114 (e.g., by protecting the IGZO during the etch process). The etch-stop layer may be made of, for example, silicon oxide, silicon nitride, silicon oxynitride, or a combination thereof (e.g., a bi- or tri-layer etch stop layer).

In some embodiments, the source electrode 112 and the drain electrode 114 are made of copper, silver, aluminum, manganese, molybdenum, tantalum, chrome, titanium, or a combination thereof. In some embodiments, the source electrode 112 and the drain electrode 114 include multiple sub-layers (e.g., sub-layers of titanium and titanium nitride). The source electrode 112 and the drain electrode 114 may have a thickness of, for example, between about 20 nm and 500 nm.

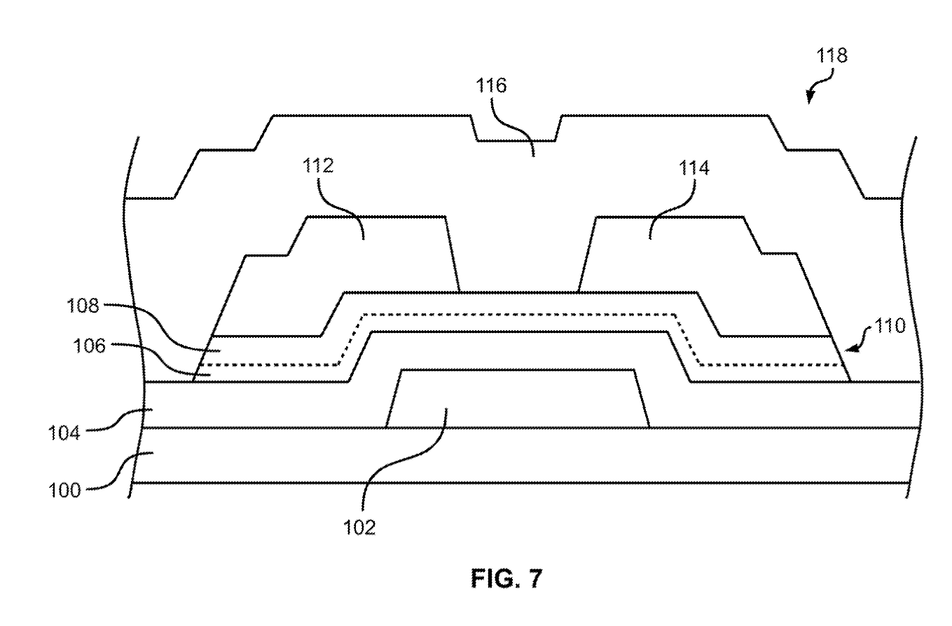

Referring to FIG. 7, a passivation layer 116 is then formed above the source electrode 112, the drain electrode 114, and the exposed portions of the gate dielectric layer 104 and the IGZO channel layer 110. In some embodiments, the passivation layer 116 is made of silicon oxide, silicon nitride, silicon oxynitride, aluminum oxide, aluminum nitride, or a combination thereof and has a thickness of, for example, between about 0.1 micrometers (μm) and about 1.5 μm.

The deposition of the passivation layer 116 may substantially complete the formation of an IGZO device 118, such as an inverted, staggered bottom-gate IGZO TFT. It should be understood that although only a single device 118 is shown as being formed above a particular portion of the substrate 100 in FIGS. 1-7, the manufacturing processes described above may be simultaneously performed on multiple portions of the substrate 100 such that multiple devices 118 are simultaneously formed, as is commonly understood. Further, although not shown, in some embodiments, such as those intended for use in display applications, pixel electrodes may also be formed above the substrate 100 during the formation of the IGZO device(s) 118. The pixel electrodes may be made of a transparent conductive material, such as indium-tin oxide (ITO).

The method for forming the IGZO described above allows the IGZO (i.e., the IGZO channel layer) to be formed with particular properties or characteristics by intentionally introducing variations within the IGZO, while still using only a single deposition process. In embodiments in which the crystalline structure (and/or mixture of crystalline and amorphous structure and/or microcrystalline structure) of the IGZO is enhanced, the electrical and chemical stability of the IGZO may be improved. When utilized in an IGZO device, such as the IGZO TFT described above, the crystalline IGZO may improve device performance, especially with respect to device reliability and stability, as well as high device performance, such as mobility, slow transistor performance (SS) speed, and leakage current. Additionally, it should be noted that the methods described herein may be easily incorporated into already-existing IGZO device manufacturing processes and equipment.

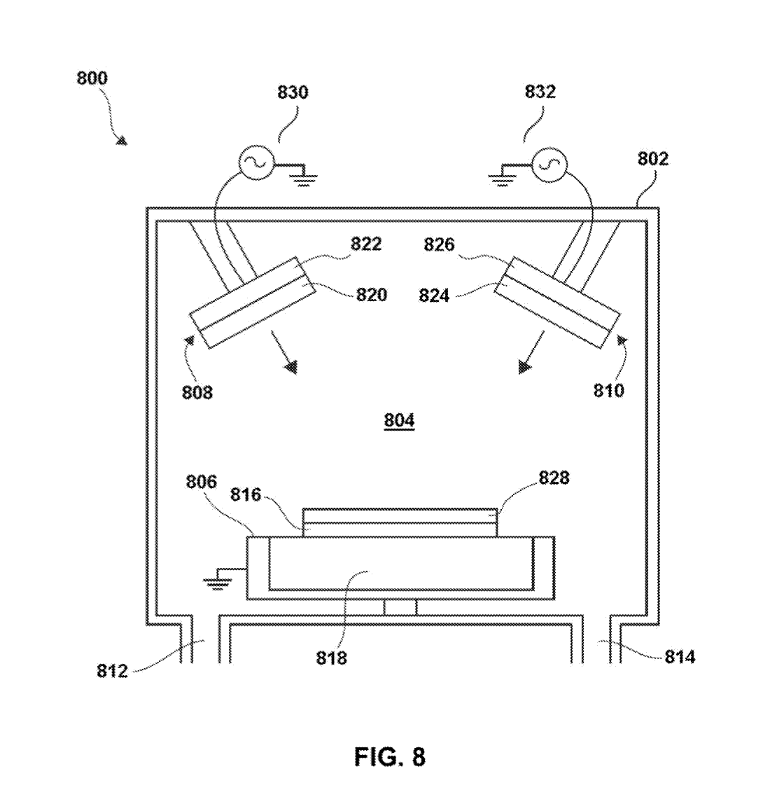

FIG. 8 provides a simplified illustration of a (stationary) physical vapor deposition (PVD) tool (and/or system) 800 which may be used, in some embodiments, to form an IGZO layer (and/or other components of the IGZO device) described above. The PVD tool 800 shown in FIG. 8 includes a housing 802 that defines, or encloses, a processing chamber 804, a substrate support 806, a first target assembly 808, and a second target assembly 810.

The housing 802 includes a gas inlet 812 and a gas outlet 814 near a lower region thereof on opposing sides of the substrate support 806. The substrate support 806 is positioned near the lower region of the housing 802 and in configured to support a substrate 816. The substrate 816 may be a round substrate having a diameter of, for example, about 200 mm or about 300 mm. In other embodiments (such as in a manufacturing environment), the substrate 816 may have other shapes, such as square or rectangular, and may be significantly larger (e.g., about 0.5 to about 4 m across). The substrate support 806 includes a support electrode 818 and is held at ground potential during processing, as indicated.

The first and second target assemblies (or process heads) 808 and 810 are suspended from an upper region of the housing 802 within the processing chamber 804. The first target assembly 808 includes a first target 820 and a first target electrode 822, and the second target assembly 810 includes a second target 824 and a second target electrode 826. As shown, the first target 820 and the second target 824 are oriented or directed towards the substrate 816. As is commonly understood, the first target 820 and the second target 824 include one or more materials that are to be used to deposit a layer of material 828 on the upper surface of the substrate 816. In some embodiments, the first and second target assemblies 808 and 810 (and/or the substrate support 806) may be movable to adjust the distance between the targets 820 and 824 and the substrate 816.

The materials used in the targets 820 and 824 may, for example, include indium, gallium, tin, zinc, silicon, silver, aluminum, manganese, molybdenum, zirconium, hathium, titanium, copper, tantalum, chrome, or any combination thereof (i.e., a single target may be made of an alloy of several metals). Additionally, the materials used in the targets may include oxygen, nitrogen, or a combination of oxygen and nitrogen in order to form oxides, nitrides, and oxynitrides. Additionally, although two targets 820 and 824 are shown, in some embodiments, a different number of targets may be used (e.g., one or more than two).

The PVD tool 800 also includes a first power supply 830 coupled to the first target electrode 822 and a second power supply 832 coupled to the second target electrode 824. As is commonly understood, in some embodiments, the power supplies 830 and 832 pulse direct current (DC) power to the respective electrodes, causing material to be, at least in some embodiments, simultaneously sputtered (i.e., co-sputtered) from the first and second targets 820 and 824. In some embodiments, the power is alternating current (AC) to assist in directing the ejected material towards the substrate 816.

During sputtering, inert gases (or a plasma species), such as argon or krypton, may be introduced into the processing chamber 804 through the gas inlet 812, while a vacuum is applied to the gas outlet 814. The inert gas(es) may be used to impact the targets 820 and 824 and eject material therefrom, as is commonly understood. In embodiments in which reactive sputtering is used, reactive gases, such as oxygen and/or nitrogen, may also be introduced, which interact with particles ejected from the targets (i.e., to form oxides, nitrides, and/or oxynitrides).

Although not shown in FIG. 8, the PVD tool 800 may also include a control system having, for example, a processor and a memory, which is in operable communication with the other components shown in FIG. 8 and configured to control the operation thereof in order to perform the methods described herein. In particular, in some embodiments, the control system is configured to control the operation of the PVD tool 800 such that the processing conditions are changed (or varied) during the formation/deposition of IGZO, as described above.

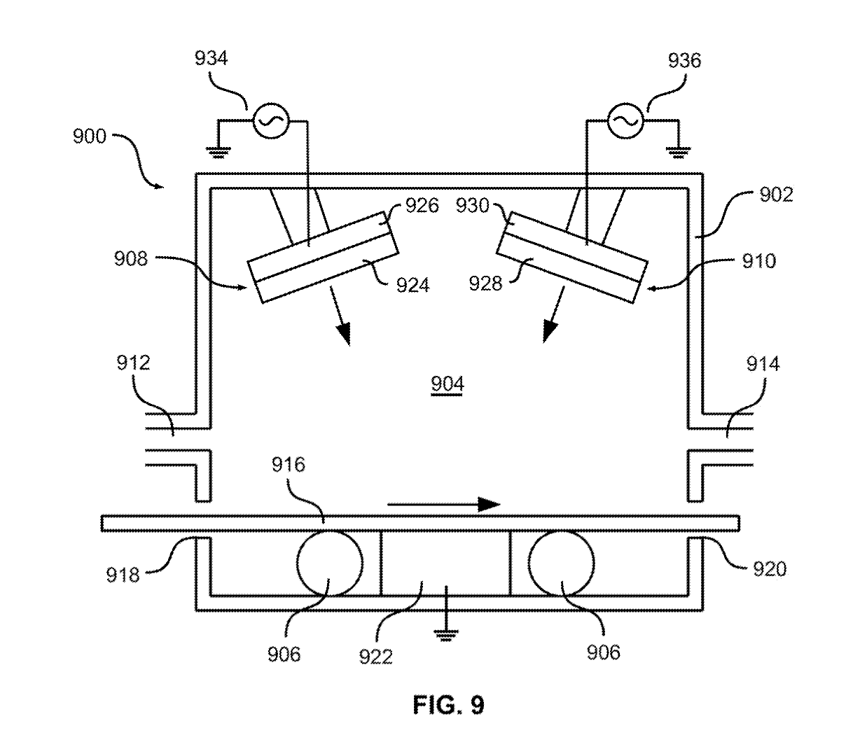

FIG. 9 provides a simplified illustration of an in-line PVD tool (and/or system) 900 which may be used, in some embodiments, to form an IGZO layer (and/or other components of the IGZO device) described above. The PVD tool 900 shown in FIG. 9 includes a housing 902 that defines, or encloses, a processing chamber 904, substrate rollers 906, a first target assembly 908, and a second target assembly 910.

The housing 902 includes a first gas manifold 912 and a second gas manifold 914 near a lower region thereof on opposing sides of the substrate rollers 906. The substrate rollers 906 are positioned near the lower region of the housing 902 and are configured to support a substrate 916 and move the substrate 916 through the processing chamber 904. More particularly, the substrate rollers 906 are configured to move the substrate 916 from a first slit 918 in the housing 902 on a side of the processing chamber 904 near the first gas manifold 912 to a second slit 918 in the housing 902 on a side of the processing chamber 904 near the second gas manifold 914.

The substrate 916 may be a round substrate having a diameter of, for example, about 200 mm or about 300 mm. In other embodiments (such as in a manufacturing environment), the substrate 916 may have other shapes, such as square or rectangular, and may be significantly larger (e.g., about 0.5 to about 4 m across). In the depicted embodiment, the housing 902 (and/or the processing chamber 904) has a width that is less than the width (or diameter) of the substrate 916 such that only a portion of the substrate 916 is positioned within the processing chamber 904 at a time. Also included in the housing 902 is a support electrode 922 which is, in some embodiments, held at ground potential during processing, as indicated.

The first and second target assemblies (or process heads) 908 and 910 are suspended from an upper region of the housing 902 within the processing chamber 904. The first target assembly 908 includes a first target 924 and a first target electrode 926, and the second target assembly 910 includes a second target 928 and a second target electrode 930. As shown, the first target 924 and the second target 928 are oriented or directed towards the center of the processing chamber 904. As is commonly understood, the first target 924 and the second target 928 include one or more materials that are to be used to deposit a layer of material on the upper surface of the substrate 916. In some embodiments, the first and second target assemblies 908 and 910 may be movable to adjust the distance between the targets 924 and 928 and the substrate 916.

The materials used in the targets 924 and 928 may, for example, include indium, gallium, tin, zinc, silicon, silver, aluminum, manganese, molybdenum, zirconium, hathium, titanium, copper, tantalum, chrome, or any combination thereof (i.e., a single target may be made of an alloy of several metals). Additionally, the materials used in the targets may include oxygen, nitrogen, or a combination of oxygen and nitrogen in order to form oxides, nitrides, and oxynitrides. Additionally, although two targets 924 and 928 are shown, in some embodiments, a different number of targets may be used (e.g., one or more than two).

The PVD tool 900 also includes a first power supply 934 coupled to the first target electrode 926 and a second power supply 936 coupled to the second target electrode 930. As is commonly understood, in some embodiments, the power supplies 934 and 936 pulse direct current (DC) power to the respective electrodes, causing material to be, at least in some embodiments, simultaneously sputtered (i.e., co-sputtered) from the first and second targets 924 and 928. In some embodiments, the power is alternating current (AC) to assist in directing the ejected material towards the substrate 916.

During sputtering, the substrate 916 may be moved (e.g., at a substantially constant speed) through the processing chamber 904 by the substrate rollers 906, while inert gases (or a plasma species), such as argon or krypton, may be introduced into the processing chamber 904 through the first and second gas manifolds 912 and 914 (a vacuum may also be applied to a vacuum manifold which is not shown). The inert gas(es) may be used to impact the targets 924 and 928 and eject material therefrom, as is commonly understood. In embodiments in which reactive sputtering is used, reactive gases, such as oxygen and/or nitrogen, may also be introduced, which interact with particles ejected from the targets (i.e., to form oxides, nitrides, and/or oxynitrides).

Although not shown in FIG. 9, the PVD tool 900 may also include a control system having, for example, a processor and a memory, which is in operable communication with the other components shown in FIG. 9 and configured to control the operation thereof in order to perform the methods described herein. For example, in some embodiments, the PVD tool 900 is operated in such a manner that an IGZO layer is formed above the substrate 916 and the processing conditions of the deposition process are varied during the process.

In particular, in some embodiments, the processing conditions in which the IGZO is deposited varies as the substrate 916 (or the particular portion of the substrate 916) is moved from the first slit 918 (or a first side of the processing chamber 904) to the second slit 920 (or a second side of the processing chamber 906). For example, the gas introduced into the processing chamber 904 through the first gas manifold 912 may have a different chemical composition (or a different flow rate, etc.) than the gas introduced into the processing chamber 904 through the second gas manifold 914. As a result, the IGZO deposited (i.e., the first sub-layer 106 in FIG. 3) above a particular portion of the substrate 916 when that portion of the substrate 916 is near the first gas manifold 912 (i.e., in a first position within the processing chamber 904) may have different properties/characteristics than the IGZO deposited (i.e., the second sub-layer 108 in FIG. 4) when that portion of the substrate 916 is near the second gas manifold 914 (i.e., in a second position within the processing chamber 904.

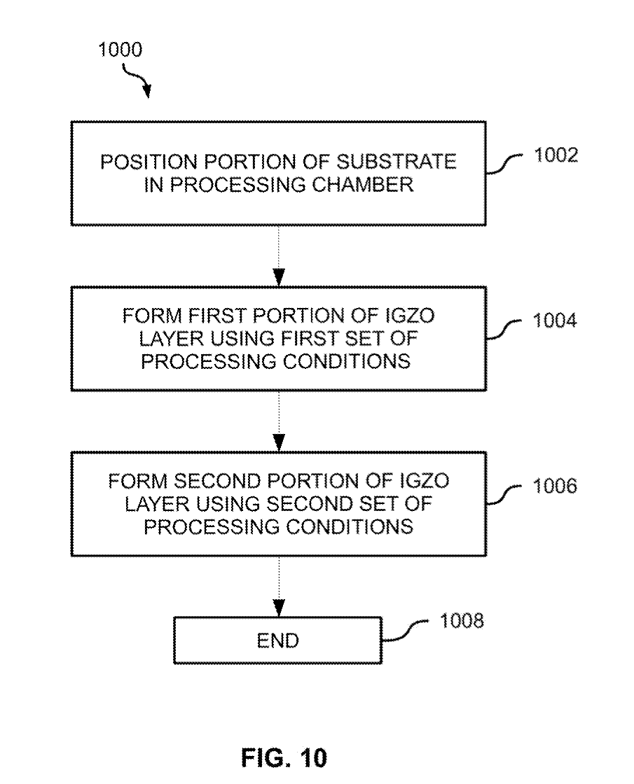

FIG. 10 illustrates a method 1000 for forming (or depositing) IGZO (and/or for forming an IGZO device, such as an IGZO TFT) according to some embodiments. At block 1002, the method 1000 begins with a substrate (or at least a portion of a substrate, such as when an in-line PVD tool us used) being positioned within a processing chamber. The processing chamber may be that of a PVD tool, which includes at least one target positioned therein. The target(s) may include indium gallium, zinc, or a combination thereof. As described above, the substrate may include glass or a flexible material, such as a polymer.

At block 1004, a first sub-layer (or portion) of an IGZO layer is formed using a first set of processing conditions. In some embodiments, the first sub-layer of the IGZO layer is formed using PVD. The first set of processing conditions may include, for example, the chemical composition, pressure, and/or flow of the gas mixture within the gaseous environment (e.g., within a processing chamber) in which the IGZO is formed, the processing temperature, target power, or a combination thereof. In some embodiments, the processing condition may (also) include the “duty cycle” at which the particular processing tool (e.g., a PVD tool) is operated, an amount of power provided to the target(s) (e.g., PVD targets), or a combination thereof.

At block 1006, a second sub-layer of the IGZO layer is formed using a second set of processing conditions, which is different than the first set of processing conditions. That is, in some embodiments, at least one of the processing conditions is changed between the formation of the first sub-layer of the IGZO layer and the second sub-layer of the IGZO layer. In some embodiments, the second sub-layer of the IGZO layer is formed in the same processing chamber as the first sub-layer of the IGZO layer. In some embodiments, the formation of the first and second sub-layers of the IGZO layer is performed using a single processing (or deposition) step, during which the processing conditions are changed. That is, the substrate (or at least a portion of the substrate) may remain in the same processing chamber between the initiation of the formation of the first sub-layer of the IGZO layer and the cessation of the formation of the second sub-layer of the IGZO layer.

In some embodiments, the IGZO layer is formed as a component (e.g., an IGZO channel layer) in an IGZO device, such as an IGZO TFT. As such, although not shown, in some embodiments, the method 1000 also includes the formation of additional components of an IGZO device, such as the gate electrode, gate dielectric layer, source/drain regions, etc. At block 1008, the method 1000 ends.

Thus, in some embodiments, methods are provided. At least a portion of a substrate is positioned in a processing chamber. A first sub-layer of an IGZO layer is formed above the at least a portion of the substrate while the at least a portion of the substrate is in the processing chamber. The first sub-layer of the IGZO layer is formed using a first set of processing conditions. A second sub-layer of the IGZO layer is formed above the first sub-layer of the IGZO layer while the at least a portion of the substrate is in the processing chamber. The second sub-layer of the IGZO layer is formed using a second set of processing conditions. The second set of processing conditions is different than the first set of processing conditions.

In some embodiments, methods are provided. A portion of a substrate is moved from a first position within a processing chamber to a second position within the processing chamber. The processing chamber includes at least one target positioned therein. Material is sputtered from the at least one target to form a first sub-layer of an IGZO layer above the portion of the substrate while the portion of the substrate is in the first position within the processing chamber. The first sub-layer of the IGZO layer is formed using a first set of processing conditions. Material is sputtered from the at least one target to form a second sub-layer of the IGZO layer above the first sub-layer of the IGZO layer while the portion of the substrate is in the second position within the processing chamber. The second sub-layer of the IGZO layer is formed using a second set of processing conditions. The second set of processing conditions is different than the first set of processing conditions.

In some embodiments, methods for forming an IGZO device are provided. A substrate is provided. A gate electrode is formed above the substrate. A gate dielectric layer is formed above the gate electrode. An IGZO layer is formed above the gate dielectric layer. The forming of the IGZO layer includes positioning at least a portion of the substrate in a processing chamber, forming a first sub-layer of the IGZO layer while the at least a portion of the substrate is in the processing chamber, wherein the first sub-layer of the IGZO layer is formed using a first set of processing conditions, and forming a second sub-layer of the IGZO channel layer while the at least a portion of the substrate is in the processing chamber, wherein the second sub-layer of the IGZO layer is formed using a second set of processing conditions. The second set of processing conditions is different than the first set of processing conditions. A source electrode and a drain electrode are formed above the IGZO layer.

Although the foregoing examples have been described in some detail for purposes of clarity of understanding, the invention is not limited to the details provided. There are many alternative ways of implementing the invention. The disclosed examples are illustrative and not restrictive.

What is claimed:

1. A method comprising:
positioning at least a portion of a substrate in a processing chamber;
forming a first sub-layer of an IGZO layer above the at least a portion of the substrate while the at least a portion of the substrate is in the processing chamber, wherein the first sub-layer of the IGZO layer is formed using a first set of processing conditions; and
forming a second sub-layer of the IGZO layer above the first sub-layer of the IGZO layer while the at least a portion of the substrate is in the processing chamber, wherein the second sub-layer of the IGZO layer is formed using a second set of processing conditions,
wherein the second set of processing conditions is different than the first set of processing conditions.

2. The method of claim 1, wherein the at least a portion of the substrate remains in the processing chamber between the initiation of the forming of the first sub-layer of the IGZO layer and the cessation of the forming of the second sub-layer of the IGZO layer.

3. The method of claim 2, wherein each of the first set of processing conditions and the second set of processing conditions comprises a chemical composition of a gaseous environment to which the at least a portion of the substrate is exposed within the processing chamber, a pressure of the gaseous environment within the processing chamber, a temperature within the processing chamber, or a combination thereof.

4. The method of claim 2, wherein each of the forming of the first sub-layer of the IGZO layer and the forming of the second sub-layer of the IZGO layer comprises sputtering material from at least one target.

5. The method of claim 4, wherein the sputtering of the material is alternating current (AC) sputtering.

6. The method of claim 5, wherein each of the first set of processing conditions and the second set of processing conditions comprises one of a duty cycle of the AC sputtering, an amount of power provided to the at least one target, or a combination thereof.

7. The method of claim 2, further comprising moving the at least a portion of the substrate from a first position to a second position between the initiation of the forming of the first sub-layer of the IGZO layer and the cessation of the forming of the second sub-layer of the IGZO layer.

8. The method of claim 7, wherein the first position is adjacent to a first side of the processing chamber and the second position is adjacent to a second side of the processing chamber.

9. The method of claim 2, further comprising:
forming a gate electrode above the at least a portion of the substrate;
forming a gate dielectric layer above the gate electrode, wherein the first sub-layer of the IGZO layer and the second sub-layer of the IGZO layer are formed above the gate dielectric layer.

10. The method of claim 9, wherein the substrate comprises glass.

11. A method comprising:
moving a portion of a substrate from a first position within a processing chamber to a second position within the processing chamber, wherein the processing chamber comprises at least one target positioned therein;
sputtering material from the at least one target to form a first sub-layer of an indium-gallium-zinc oxide (IGZO) layer above the portion of the substrate while the portion of the substrate is in the first position within the processing chamber, wherein the first sub-layer of the IGZO layer is formed using a first set of processing conditions; and
sputtering material from the at least one target to form a second sub-layer of the IGZO layer above the first sub-layer of the IGZO layer while the portion of the substrate is in the second position within the processing chamber, wherein the second sub-layer of the IGZO layer is formed using a second set of processing conditions,
wherein the second set of processing conditions is different than the first set of processing conditions.

12. The method of claim 11, wherein the portion of the substrate remains in the processing chamber between the initiation of the forming of the first sub-layer of the IGZO layer and the cessation of the forming of the second sub-layer of the IGZO layer.

13. The method of claim 12, wherein the sputtering of the material from the at least one target is alternating current (AC) sputtering, and wherein each of the first set of processing conditions and the second set of processing conditions comprises a chemical composition of a gaseous environment to which the portion of the substrate is exposed within the processing chamber, a pressure of the gaseous environment within the processing chamber, a temperature within the processing chamber, a duty cycle of the AC sputtering, an amount of power provided to the at least one target, or a combination thereof.

14. The method of claim 13, wherein the portion of the substrate is moved between the first position within the processing chamber to the second position within the processing chamber at a substantially constant speed between the initiation of the forming of the first sub-layer of the IGZO layer and the cessation of the forming of the second sub-layer of the IGZO layer.

15. The method of claim 14, further comprising:
forming a gate electrode above the portion of the substrate;
forming a gate dielectric layer above the gate electrode, wherein the first sub-layer of the IGZO layer and the second sub-layer of the IGZO layer are formed above the gate dielectric layer.

16. A method for forming an indium-gallium-zinc oxide (IGZO) device, the method comprising:
providing a substrate;
forming a gate electrode above the substrate;
forming a gate dielectric layer above the gate electrode;
forming an IGZO layer above the gate dielectric layer, wherein the forming of the IGZO layer comprises:
positioning at least a portion of the substrate in a processing chamber;
forming a first sub-layer of the IGZO layer while the at least a portion of the substrate is in the processing chamber, wherein the first sub-layer of the IGZO layer is formed using a first set of processing conditions; and
forming a second sub-layer of the IGZO layer while the at least a portion of the substrate is in the processing chamber, wherein the second sub-layer of the IGZO layer is formed using a second set of processing conditions,
wherein the second set of processing conditions is different than the first set of processing conditions; and
forming a source electrode and a drain electrode above the IGZO layer.

17. The method of claim 16, wherein the at least a portion of the substrate remains in the processing chamber between the initiation of the forming of the first sub-layer of the IGZO layer and the cessation of the forming of the second sub-layer of the IGZO layer.

18. The method of claim 17, wherein each of the forming of the first sub-layer of the IGZO layer and the forming of the second sub-layer of the IZGO layer comprises sputtering material from at least one target, and wherein the sputtering is alternating current (AC) sputtering.

19. The method of claim 18, wherein each of the first set of processing conditions and the second set of processing conditions comprises a chemical composition of a gaseous environment to which the at least a portion of the substrate is exposed within the processing chamber, a pressure of the gaseous environment within the processing chamber, a temperature within the processing chamber, a duty cycle of the AC sputtering, an amount of power provided to the at least one target, or a combination thereof.

20. The method of claim 19, further comprising forming a passivation layer above the source electrode and the drain electrode.
